(19) United States
(12) Patent Application Publication
(10) Pub. No.: US 2008/0296700 A1
(43) Pub. Date: Dec. 4, 2008

(54) METHOD OF FORMING GATE PATTERNS FOR PERIPHERAL CIRCUITRY AND SEMICONDUCTOR DEVICE MANUFACTURED THROUGH THE SAME METHOD

(75) Inventor: Chun-Soo KANG, Seoul (KR)

Correspondence Address: TOWNSEND AND TOWNSEND AND CREW, LLP, TWO EMBARCADERO CENTER, EIGHTH FLOOR, SAN FRANCISCO, CA, 94111-3834, US

(73) Assignee: Hynix Semiconductor Inc., Icheon-si (KR)

(21) Appl. No.: 11/951,201

(22) Filed: Dec. 5, 2007

(30) Foreign Application Priority Data
May 28, 2007 (KR) 10-2007-0051521

(51) Int. Cl. H01L 27/088; H01L 21/283

(52) U.S. Cl. 257/390; 438/587; 257/E27.06; 257/E21.177

(57) ABSTRACT

A method for forming gate patterns for a semiconductor device includes defining a cell array region and a peripheral region on a substrate. A layout is defined in a peripheral region. The layout comprises patterns having a plurality of fingers that extend along a first direction, wherein the fingers are spaced apart from adjacent fingers in a second direction at substantially the same interval, the patterns including gate patterns.

### CROSS-REFERENCES TO RELATED APPLICATION

The present application claims priority to Korean application number 10-2007-0051521, filed on 28 May, 2007, which is incorporated by reference in its entirety.

### BACKGROUND OF THE INVENTION

The present invention relates to a semiconductor device, and more particularly, to a method of forming gate patterns for a peripheral region of a memory device, and a structure of a semiconductor device manufactured through the same method.

As a memory semiconductor device becomes highly integrated, a critical dimension (CD) of circuit patterns is reduced to integrate more circuits in a limited area. Accordingly, efforts to create more uniformly formed patterns with a smaller CD have been made. Resolution enhancement technology is used in a photolithography exposure process for transferring designed circuit patterns onto a wafer. As one of several resolution enhancement technologies, an asymmetric modified illumination system such as dipole illumination is introduced to an exposure process. For example, in the case where a dipole illumination system is introduced, circuit patterns (e.g., lines and spacing) can be realized in a finer and more precise manner.

In the case of a memory semiconductor device, for example, a dynamic random access memory (DRAM), cell gate patterns can be designed in a line and a space shape in a cell array region to form a memory cell. Accordingly, during the formation of the cell gate patterns, the CD and uniformity of patterns can be secured using the resolution enhancement technology. Therefore, the modified illumination system is suitably selected for the cell array region to realize a CD, uniformity, and a process margin for patterns in a cell array region.

Transistors forming a peripheral circuitry for driving and controlling a memory cell include peripheral gate patterns set to have a relatively large pitch compared to that of cell region transistor gate patterns. Also, the peripheral gate patterns are formed to have various gate lengths and pitches between gates depending on the construction of the peripheral circuitry. Accordingly, while an optical proximity correction process is performed, OPC accuracy is difficult to realize. Also, a local etch loading effect can be caused by the varying structure densities, which makes it difficult to form peripheral gate patterns at a required CD.

Referring to FIG. 1, a transistor forming a peripheral circuitry in a peripheral region 10 includes gate patterns 40 and source/drain regions. The gate patterns 40 are disposed in an active region 30 defined by a device isolation layer 20. The source/drain regions are formed in the active region 30 adjacent to the gate patterns 40. The above-described transistor is formed as a circuit by interconnection contacts and local interconnection layers, or connected to a word line or a bit line. The active region 30 can be defined by the device isolation layer 20 to include first, second, and third active regions 31, 33, 35 having different sizes, depending on the kind of peripheral circuitry. The gate patterns 40 are disposed across the active region 30. At this point, a first spacing ‘d1’ between a first gate pattern 41 on the first active region 31, and a second spacing ‘d2’ between the first gate pattern 41 and a second gate pattern 43 on the second active region 33 have different sizes. This is because a first transistor including the first gate pattern 41, and a second transistor including the second gate pattern 43 are used to form peripheral circuits of different kinds.

The second spacing ‘d2’ between the first gate pattern 41 and the second gate pattern 43 is set depending not only on the width of the first active region 31 and the width of the second active region 33, but also on the width of a device isolation region 37 isolating the first active region 31 and the second active region 33. Meanwhile, the first spacing ‘d1’ between the first gate patterns 41 is set with consideration of the spacing of adjacent first gate patterns 41. Therefore, a difference is generated to the first spacing ‘d1’ and the second spacing ‘d2’.

Meanwhile, a dummy pattern 50 can be disposed between the first active region 31 and the third active region 35 separated by a portion of the device isolation region 20 having a wider width. The dummy pattern 50 is introduced to suppress generation of optical errors on the transfer to the gate pattern 40 upon exposure, and generation of an etching loading effect upon etching due to considerable spacing between the gate patterns over the first and third active regions 31 and 35. Differences are generated in a third spacing ‘d3’ between the first gate pattern 41 and the dummy pattern 50, in the second spacing ‘d2’ between the first gate pattern 41 and the second gate pattern 43, and in the first spacing ‘d1’ between the first gate patterns 41.

The differences between the first, second, and third spacings ‘d1’, ‘d2’, and ‘d3’ cause optical errors upon exposure for pattern transfer. Also, different etching loading effects can be applied to the gate patterns 40. Accordingly, it is difficult to form the gate patterns 40 so that they have a uniform CD. Therefore, development of a method for more uniformly forming the CD of the gate patterns 40 is required.

### SUMMARY OF THE INVENTION

Embodiments of the present invention are directed to a method of forming gate patterns for transistors of a peripheral circuitry that can more uniformly realize a CD, and a semiconductor device manufactured through the same method.

In one embodiment, a method for forming gate patterns includes: making a layout in a peripheral region of a semiconductor device, the layout including the gate patterns arranged such that the gate patterns have an equal spacing to that of other patterns at an adjacent equal level; and transferring the layout of the gate patterns onto a wafer.

The other patterns at the equal level may be second gate patterns having an equal critical dimension (CD) to that of the gate patterns. Also, the other patterns on the equal level may be dummy patterns disposed adjacent to the gate patterns.

In another embodiment, a method for forming gate patterns includes: making a layout of a device isolation region in a peripheral region of a semiconductor device, the device isolation region defining first and second active regions; making a layout of gate patterns that cross the first and second active regions such that first spacings between adjacent gate patterns are equal to each other; inserting dummy patterns on a portion of the device isolation region that is located between the first and second active regions such that the dummy patterns have a second spacing equal to the first spacing between the adjacent gate patterns; and transferring the layouts of the gate patterns and the dummy patterns onto a wafer.

The gate patterns may be set to have an equal CD between the gate patterns. The dummy patterns may be set to have a CD having a size of approximately 100% to approximately 150% of the CD of the gate patterns.

The method may further include controlling the first spacing of the gate patterns such that a separation margin is secured between the dummy pattern and edges of the first and second active regions.

The method may further include controlling a CD of the dummy pattern such that a separation margin is secured between the dummy pattern and edges of the first and second active regions.

The method may further include: making a layout of interconnection contacts to be connected to portions of the first and second active regions that are exposed adjacent to the gate patterns; and controlling the first spacing of the gate patterns such that an overlap margin is secured between the interconnection contacts and the gate patterns.

The method may further include: making a layout of interconnection contacts to be connected to portions of the first and second active regions that are exposed adjacent to the gate patterns; and controlling the first spacing of the gate patterns such that an overlap margin is secured between the interconnection contacts and edges of the first and second active regions.

In still another embodiment, a semiconductor device includes: first and second active regions in a peripheral region of a semiconductor device, the first and second active regions being defined by a device isolation region; gate patterns having a layout set to cross the first and second active regions, first spacings of the gate patterns being set to equal to each other; and dummy patterns inserted on a portion of the device isolation region that is located between the first and second active regions, the dummy patterns having a second spacing equal to the first spacing between adjacent gate patterns.

The present invention can provide a method for forming gate patterns for transistors of a peripheral circuitry that can more uniformly realize an actual CD matching with an object CD.

In an embodiment of the present invention, a layout is designed such that gate patterns of transistors for a peripheral circuitry formed in a peripheral region of a memory semiconductor device are formed to have a constant spacing equal to that of other adjacent patterns, so that the gate patterns in the peripheral region are more regularly arranged. The layout of the gate patterns in the peripheral region is transferred using an exposure process, so that actual gate patterns are formed on a wafer. Accordingly, pattern transfer non-uniformity by non-uniformity of an optical proximity effect during an exposure process, or etching non-uniformity by variation of a local etch loading effect during an etching process after an exposure can be suppressed. Also, the layout of the gate patterns is designed to have better regularity, so that accuracy during an OPC can be improved even more. Therefore, the gate patterns can be more uniformly formed to match with an object CD even more.

### BRIEF DESCRIPTION OF THE DRAWINGS

FIG. 1 illustrates a schematic layout explaining arrangement of gate patterns in a peripheral region of a conventional memory semiconductor device.

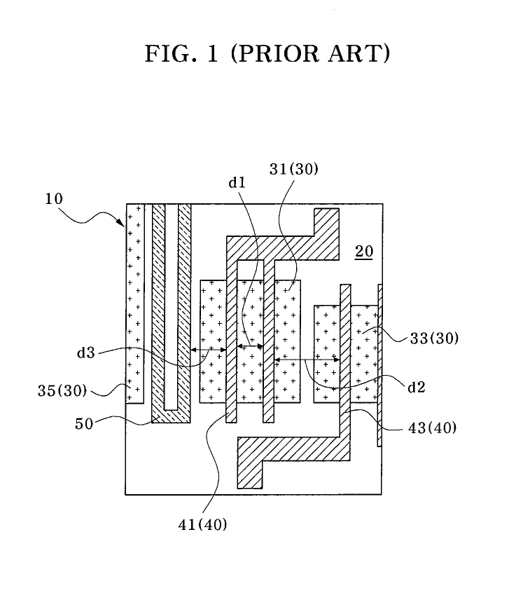

FIG. 2 illustrates a schematic view explaining arrangement of a peripheral region of a memory semiconductor device according to an embodiment of the present invention.

FIG. 3 illustrates a layout explaining a method for forming gate patterns and a semiconductor device manufactured through the same method according to an embodiment of the present invention.

### DESCRIPTION OF SPECIFIC EMBODIMENTS

Hereinafter, a method of forming gate patterns for circuitry in a peripheral region (or “peripheral circuit” or “peripheral circuitry”), and a semiconductor device manufactured through the same method in accordance with the present invention will be described in detail with reference to the accompanying drawings.

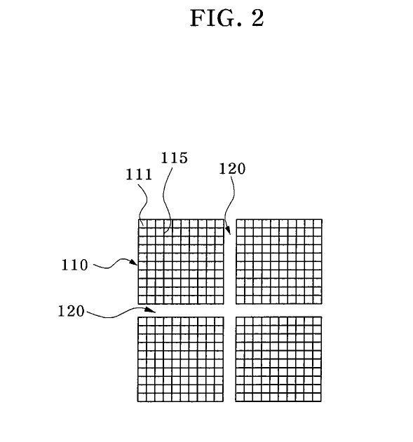

Referring to FIG. 2, core regions 115 between sub cell array regions 111 are disposed to form cell array regions 110 or banks in a memory semiconductor device such as a dynamic random access memory (DRAM) device. A peripheral region 120 is located at a portion between the cell array regions 110 or an outer peripheral portion. A variety of peripheral circuits such as a circuit for addressing memory cells repeatedly disposed in the sub cell array region 111, or a main word line driver (MWD) for driving cell transistors, a Y decoder, a data bus sense amplifier (DB S/A), or a voltage generator are disposed in the peripheral region 120. An embodiment of the present invention proposes a method of more accurately forming the gates of transistors in this peripheral circuitry by more uniformly spacing the gates.

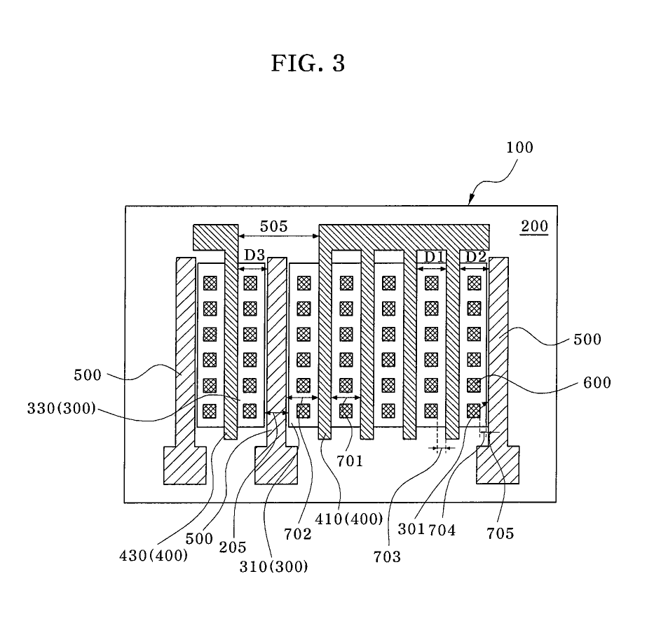

Referring to FIG. 3, in a method of forming gate patterns according to an embodiment of the present invention, a layout of gate patterns is designed for application in forming gate patterns in a peripheral circuitry of a memory semiconductor device. First, a peripheral region 100 where transistors forming a peripheral circuitry is defined. Gate patterns 400 extending across active regions 300 defined by a device isolation region 200 are disposed within the peripheral region 100. At this point, a design rule is set such that the gate patterns 400 have a spacing ‘D’ (D1, D2, and D3 are collectively referred to as D) substantially equal to that of patterns adjacent to each gate pattern 400, for example, other gate patterns 400 or dummy patterns 500 that are adjacent to the gate pattern 400. Accordingly, a layout of the gate patterns 400 is made with a regular pattern arrangement. Each of the gate pattern 400 and dummy pattern 500 has one or more fingers (or lines) that extend along a first direction (or a vertical direction depending on the orientation used). A pattern having two or more fingers is provided with a connector to connect the fingers in the present embodiment. The connector may not be used or used to connect only part of the fingers in other embodiments. Spacing ‘D’ (e.g., D1, D2, and D3) refers to a distance between adjacent fingers along a second direction (e.g., lateral direction) that is orthogonal to the first direction.

To allow the particular gate patterns 400 to have the spacing ‘D’ equal to that of adjacent patterns, an object peripheral region 100 where the spacing ‘D’ of the gate patterns 400 is to be controlled equal to that of the adjacent patterns can be selected from the entire peripheral region 120 (of FIG. 2). Since transistors of various sizes are disposed in the entire peripheral region 120 to form peripheral circuits of various shapes, a region where gate patterns having an equal object CD are disposed can be selected as an object peripheral region 100. Therefore, a layout can be designed such that the gate patterns 400 within the object peripheral region 100 of FIG. 3 have a substantially consistent CD, for example, a CD of approximately 120 nm. Since the gate patterns 400 are set to have an equal gate length, and also, the spacing ‘D’ from adjacent patterns is set to an equal size, the pitch of the gate patterns 400 is constant or substantially thereto.

Referring back to FIG. 3, an overlap margin with respect to a pattern layout of a layer of a different level from that of the gate patterns 400 can be considered when a design rule regarding the spacing ‘D’ of the gate patterns 400 is set. For example, the spacing ‘D’ of the gate patterns 400 can be set with consideration of an overlap margin of the gate patterns 400 and the interconnection contacts 600. The gate patterns 400 are disposed to cross the active regions 300 defined by the device isolation region 200. Source/drain regions are formed in portions of the active region 300 that are exposed adjacent to the gate patterns 400, and the interconnection contacts 600 are connected to the source/drain regions. Therefore, open widths 701 and 703 of the portions of the active region 300 that are exposed adjacent to the gate patterns 400 are primarily set such that the overlap margin 703 of the interconnection contacts 600 and the gate patterns 400 is secured.

Accordingly, a first open width 701 of a first active region 310 that is exposed between two adjacent first gate patterns 410 within the first active region 310 is set as sum of a CD of the interconnection contact 600 and two times the overlap margin 703 of the interconnection contact 600 and the gate patterns 400. Since the first open width 701 is equal to a first spacing ‘D1’ between first gate patterns 410, the size of the first spacing ‘D1’ can be set depending on the overlap margin 703 of the interconnection contacts 600 and the gate patterns 400.

For example, in the case where the CD of the first gate patterns 410 is set to a size of approximately 120 nm, the overlap margin of the interconnection contacts 600 can be set to approximately 80 nm. In this case, the overlap margin of the interconnection contacts 600 and the first gate patterns 410 is set to approximately 60 nm, so that the first spacing ‘D1’ between the first gate patterns 410 can be set to 200 nm. This design rule can be set by appraising an overlap margin of the first gate patterns 410 and the interconnection contacts 600, an overlap margin of the interconnection contacts 600 and the active region 300, an overlap of a bit line, which is an upper line layer electrically connected to the interconnection contacts 600, a process margin change depending on a pitch set between the first gate patterns 410, and a gap fill margin of an interlayer insulating layer with respect to the first spacing ‘D1’ between the first gate patterns 410.

Referring to FIG. 3, in the case where transistors forming a peripheral circuitry are isolated by the device isolation region 200 to form a different kind of peripheral circuitry, the first active region 310 can be separated from the second active region 330 by the width of a separation portion 205 of the device isolation region 200 therebetween. Due to this separation, a spacing 505 between the first gate patterns 410 disposed on the first active region 310 and the second gate patterns 430 disposed on the second active region 330 can have a considerable difference, for example, a difference of two times or more compared to the first spacing ‘D1’ between the first gate patterns 410.

In this case, dummy patterns 500 can be introduced on the separation portion 205 of the device isolation region 200. The dummy patterns 500 can be introduced to have a second spacing ‘D2’ and a third spacing ‘D3’ from an adjacent first gate pattern 410 and an adjacent second gate pattern 430, respectively. At this point, the second and third spacings ‘D2’ and ‘D3’ are set to have a size substantially equal to the first spacing ‘D1’ to allow spacings ‘D’ between the gate pattern 400 and adjacent patterns to have a substantially equal size. For this purpose, the CD of the dummy patterns 500 and the width of the separation portion of the device isolation region 200 can be readjusted.

Since the dummy patterns 500 are introduced to realize a more uniform etch effect on the whole by effectively controlling a local etch loading effect, the CD of the dummy patterns 500 can be set to have a size of approximately 100% to approximately 150% greater than the CD of the gate patterns 400 to realize this effect. When the size of the dummy patterns 500 is 150% greater than the CD of the gate patterns 400, generation of a local etch loading effect by the dummy patterns 500 is expected. Therefore, the size of the dummy patterns 500 can be limited to less than approximately 150% of the CD of the gate patterns 400. Meanwhile, when the dummy patterns 500 overlap the first and second active regions 310 and 330, electrical errors may be generated. Therefore, the dummy patterns 500 need to be disposed to secure a separation margin 705 from an edge 301 of the active region 300.

The width of the active region 300 or the location of the edge 301 can be adjusted or the CD of the dummy patterns 500 can be adjusted so that the dummy patterns 500 are disposed to secure the separation margin 705. At this point, when the width of the active region 300 is adjusted and thus the location of the edge 301 is adjusted to secure the separation margin 705, an appraisal should be made such that an overlap margin 704 (i.e., a separation margin of the interconnection contacts 600 connected to the active region 300) and the edge 301 is secured.

For example, in the case where the gate patterns 400 are set to have a gate length of approximately 120 nm and the first spacings ‘D1’ are set to 200 nm, a spacing between the interconnection contacts 600 having a CD of approximately 80 nm and the edge 301 of the active region 300, that is, the overlap margin 704 can be set to approximately 45 nm. Accordingly, to maintain the second and third spacings ‘D2’ and ‘D3’ to a size equal to that of the first spacing ‘D1’, the separation margin 705 can be set to 15 nm. After whether an error during an actual process is generated is checked, a design rule for the separation margin 705 and the overlap margin 704 is set as a design rule to be actually applied. After the design rule is set, whether this design rule is suitable for an actual process is examined and appraised before the final design rule is determined. A layout of the gate patterns 400 is designed and created according to the above-determined design rule for the CD and margins as illustrated in FIG. 3.

Meanwhile, in the case where a plurality of dummy patterns 500 are arranged in parallel, a spacing between the dumpy patterns 500 can be set to a size equal to that of the second spacing ‘D2’ and the third spacing ‘D3’. Accordingly, even in the case where the plurality of dummy patterns 500 are arranged in parallel, arrangement regularity can be maintained.

Mask patterns conforming to the layout of the above-designed gate patterns 400 is formed on a photomask, and the layout is transferred onto a wafer through exposure using the photomask. After that, a gate layer on the wafer is selectively etched using the transferred patterns through the exposure, for example, photoresist patterns from an etch mask to form actual gate patterns. At this point, the actual gate patterns are formed to conform to the layout of the gate patterns 400 of FIG. 3.

During the pattern transferring process, the layout of the gate patterns 400 of FIG. 3 can induce actual gate layer patterns having higher uniformity. That is, since the layout of the gate patterns 400 is designed to have a spacing D equal to that of surrounding patterns (e.g., gate patterns 430 and dummy patterns 500), pattern arrangement regularity having higher uniformity can be obtained. Therefore, a more uniform optical proximity effect is induced in the peripheral region 100 upon exposure, so that transferring of gate patterns 400 can be more uniformly produced.

Also, since the layout of the gate patterns 400 provides a considerably regular pattern arrangement, when a local optical proximity effect is caused upon pattern transferring, that is, when a pattern transfer error is generated, an OPC process for correcting the optical errors can be performed more elaborately and more accurately. Therefore, the accuracy of the OPC can be improved.

Furthermore, since the gate patterns 400 and the dummy patterns 500 are arranged to have an equal spacing, a local etch loading effect can be suppressed while the gate layer on the wafer is selectively etched. Accordingly, while actual gate layer patterns conforming to the layout of the gate patterns 400 are formed, it is possible to allow a uniform etch bias to be applied to a peripheral region. Therefore, gate layer patterns can be formed to an object CD set by the layout of the gate patterns 400 with defective patterns suppressed.

According to the present invention, a CD margin and uniformity of gate patterns of transistors in a peripheral region of a memory semiconductor device can be secured. Therefore, the characteristics of a semiconductor device can improve and yield can increase.

While the present invention has been described with respect to the specific embodiments, it will be apparent to those skilled in the art that various changes and modifications may be made without departing from the spirit and scope of the invention as defined in the following claims.

What is claimed is:

1. A method for forming gate patterns for a semiconductor device, the method comprising:
defining a cell array region and a peripheral region on a substrate; and
defining a layout in the peripheral region, the layout comprising patterns having a plurality of fingers that extend along a first direction, wherein the fingers are spaced apart from adjacent fingers in a second direction at substantially the same interval, the patterns including gate patterns.

2. The method of claim 1, wherein the gate patterns are defined to have an equal critical dimension (CD) between the fingers.

3. The method of claim 1, wherein the patterns include dummy patterns.

4. The method of claim 1, wherein the patterns include dummy patterns disposed adjacent to the gate patterns, wherein the gate patterns includes include a connector that connects two or more fingers.

5. The method of claim 4, wherein the dummy patterns are defined to have a critical dimension (CD) having a size of approximately 100% to approximately 150% of a CD of the gate patterns.

6. A method for forming gate patterns, the method comprising:
defining an isolation region in a peripheral region of a semiconductor substrate, the isolation region defining first and second active regions;
defining gate patterns in the first and second active regions, each gate pattern including one or more fingers that extend along a first direction, each finger being spaced apart from an adjacent finger by a first spacing, the first spacing being a distance along a second direction; and
providing a dummy pattern on a portion of the isolation region that is located between the first and second active regions, the dummy pattern having at least one finger that extend along the first direction,
wherein the finger of the dummy pattern and the finger of the gate pattern adjacent thereto are spaced apart from each other by a second spacing that is substantially the same as the first spacing.

7. The method of claim 6, wherein the gate patterns are defined to have an equal critical dimension (CD) between the fingers of the gate patterns.

8. The method of claim 6, wherein the dummy patterns are defined to have a critical dimension (CD) having a size of approximately 100% to approximately 150% of the CD of the gate patterns.

9. The method of claim 6, further comprising controlling the first spacing of the gate patterns such that a separation margin is secured between the dummy pattern and edges of the first and second active regions.

10. The method of claim 6, further comprising controlling a CD of the dummy pattern such that a separation margin is secured between the dummy pattern and edges of the first and second active regions.

11. The method of claim 6, further comprising:
defining interconnection contacts in portions of the first and second active regions that are exposed adjacent to the gate patterns; and
adjusting the first spacing of the gate patterns such that an overlap margin is secured between the interconnection contacts and the fingers of the gate patterns.

12. The method of claim 6, further comprising:
defining interconnection contacts in portions of the first and second active regions that are exposed adjacent to the gate patterns; and
adjusting the first spacing of the gate patterns such that an overlap margin is secured between the interconnection contacts and edges of the first and second active regions.

13. A semiconductor device comprising:
first and second active regions in a peripheral region of a semiconductor device, the first and second active regions being defined by a isolation region;
a gate pattern having fingers that extend along a vertical direction in the first and second active regions, each finger of the gate pattern being spaced apart from an adjacent finger by a first interval in a lateral direction; and
a dummy pattern defined on a portion of the isolation region that is located between the first and second active regions, the dummy pattern having at least one finger that is separated from an adjacent finger by a second interval in the lateral direction, the first and second interval being substantially the same value.

14. The semiconductor device of claim 13, wherein the fingers of the gate pattern have an equal critical dimension (CD).

15. The semiconductor device of claim 13, wherein the dummy pattern has a CD having a size of approximately 100% to approximately 150% of that of the gate patterns.
